(19) United States
(12) Patent Application Publication
(10) Pub. No.: US 2025/0096007 A1
(43) Pub. Date: Mar. 20, 2025

(54) SUBSTRATE TREATING APPARATUS AND SUBSTRATE TREATING METHOD

(71) Applicant: SEMES CO., LTD., Cheonan-si (KR)

(72) Inventors: Jae Seung YU, Seoul (KR); Sung Hun EOM, Hwaseong-si (KR); Hee Man AHN, Seoul (KR); Gyeong Won SONG, Cheonan-si (KR); Gu Won SEON, Seoul (KR); Sol AN, Suwon-si (KR)

(73) Assignee: SEMES CO., LTD., Cheonan-si (KR)

(21) Appl. No.: 18/882,906

(22) Filed: Sep. 12, 2024

(30) Foreign Application Priority Data
Sep. 19, 2023 (KR) 10-2023-0124935

(51) Int. Cl. H01L 21/324; G03F 7/16; H01L 21/033

(52) U.S. Cl. CPC H01L 21/324; H01L 21/033; G03F 7/16

(57) ABSTRACT

A method of treating a substrate treats a substrate by using a substrate treating apparatus that includes a main supply line connected to a humidified gas supply line and a dry gas supply line, having a first region in which a first heater is installed, and a second region located downstream of the first region. The method includes a heating operation of heating the second region with the dry gas heated in the first region by supplying the dry gas into the main supply line in a state where the first heater is controlled to heat the first region; and a substrate treating operation of supplying the humidified gas into the main supply line after the heating operation and allowing the humidified gas to pass through the first region and the second region and to be supplied into the treatment space to treat the substrate disposed in the treatment space.

### CROSS-REFERENCE TO RELATED APPLICATIONS

This application claims priority to and the benefit of Korean Patent Application No. 10-2023-0124935 filed in the Korean Intellectual Property Office on Sep. 19, 2023, the entire contents of which are incorporated herein by reference.

### TECHNICAL FIELD

The present invention relates to a substrate treating apparatus and method, and more particularly, to an apparatus and a method of heat treating a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

However, with the recent integration of semiconductor devices, micro-patterning of the resist pattern is required. To realize the micro-pattern of resist patterns, an exposure process using Extreme UltraViolet (EUV) light has been proposed. Since the exposure process using EUV light requires resist with high resolution, high etch resistance, and high sensitivity to exposure, metal-containing resist (hereinafter referred to as “metal-containing resist”) is being used as a resist.

After the exposure process is completed, a post-exposure baking process is performed. During the bake process after the exposure, humidified gas containing moisture is supplied to the substrate on which metal-containing resist is formed. Humidified gas is heated in the supply process to prevent condensation of moisture in the gas. Typically, a line heater is installed in a line where the humidified gas is supplied to heat the gas. However, due to the structure of the line or interference with other equipment or components, it is sometimes difficult to install a line heater in some areas of the line. For example, the above some areas may be where the line is connected with a chamber. A region where the line heater cannot be installed does not provide enough heat to the humidified gas, and the temperature of the humidified gas passing through the region is reduced. When the temperature of the humidified gas decreases below the dew point temperature, the moisture in the humidified gas condenses. Moisture condensation may form watermarks on the substrate and cause defects.

### SUMMARY OF THE INVENTION

The present invention has been made in an effort to provide a substrate treating apparatus and method that are capable of preventing defects from being generated on a substrate when the substrate is heated.

The present invention has also been made in an effort to provide a substrate treating apparatus and method that are capable of preventing moisture from condensing when treating a substrate by using humidified gas containing moisture, even when a line heater is not provided in some areas of a line supplying the humidified gas.

The present invention has also been made in an effort to provide a substrate treating apparatus and method that are capable of supplying humidified gas containing moisture while stably maintaining humidity of the humidified gas.

The object of the present invention is not limited thereto, and other objects not mentioned will be clearly understood by those of ordinary skill in the art from the following description.

An exemplary embodiment of the present invention provides an apparatus for treating a substrate, the apparatus including a housing providing an inner space; a heat treating chamber provided in the inner space and providing a treatment space in which a heating process of the substrate is carried out; a transfer plate provided in the inner space, and for loading the substrate into the treatment space or unloading the substrate from the treatment space; a gas supply unit for supplying gas to the treatment space; and a controller for controlling the gas supply unit, in which the gas supply unit includes: a humidified gas supply line which supplies humidified gas containing moisture, in which a first valve is installed; a dry gas supply line which supplies dry gas to the treatment space, in which a second valve is installed; a main supply line connected with the humidified gas supply line and the dry gas supply line; and a first heater installed in the main supply line, the main supply line has: a first region in which the first heater is installed; and a second region located downstream of the first region and in which the first heater is not installed, and the controller controls the gas supply unit to perform: a heating operation of controlling the first heater to heat the first region, and opening the second valve to heat the second region with the dry gas; and a substrate treating operation of opening the first valve after the heating operation, and treating the substrate by supplying the humidified gas to the treatment space

According to the exemplary embodiment, the apparatus may further include a temperature sensor for measuring a temperature of the second region.

According to the exemplary embodiment, the temperature sensor may be provided to a region of the second region adjacent to the chamber, and the controller may control the heating operation to be performed when a temperature measured from the temperature sensor is below a preset temperature value.

According to the exemplary embodiment, the controller may open the first valve and close the second valve to allow the dry gas to be supplied to the main supply line after the temperature of the second region reaches the preset temperature value.

According to the exemplary embodiment, the controller may open the first valve to allow the dry gas to be supplied to the main supply line after the temperature of the second region reaches the preset temperature value, and the second valve may be a flow control valve.

According to the exemplary embodiment, the controller may control the substrate to be loaded into the treatment space after the temperature of the second region reaches the preset temperature value.

According to the exemplary embodiment, the apparatus may further include a second heater installed in the dry gas supply line to heat the dry gas supply line.

According to the exemplary embodiment, the gas supply unit may include: a gas supply line for supplying gas; a gas supply source connected to the gas supply line; a humidifying device installed on the gas supply line; a bypass line for supplying the gas while bypassing the humidifying device on the gas supply line; a first valve installed on the bypass line; and a second valve installed on the gas supply line, and the bypass line is branched from the gas supply line upstream of the humidifying device and connected to the main gas supply line, and the first valve may be installed between a point where the bypass line is branched from the gas supply line and the humidifying device.

According to the exemplary embodiment, the preset temperature value may be a temperature higher than a dew point of the humidified gas.

According to the exemplary embodiment, the humidified gas may be air containing moisture, and the dry gas may be inert gas, N₂, or air.

According to the exemplary embodiment, the gas may be air.

Another exemplary embodiment of the present invention provides a method of treating a substrate, which treats a substrate by using a substrate treating apparatus, the substrate treating apparatus including: a heat treating chamber providing a treatment space in which a heating process of a substrate is carried out; a humidified gas supply line for supplying humidified gas containing moisture to the treatment space; a dry gas supply line for supplying dry gas to the treatment space; and a main supply line connected to the humidified gas supply line and the dry gas supply line, having a first region in which a first heater is installed, and a second region located downstream of the first region, the method including: a heating operation of heating the second region with the dry gas heated in the first region by supplying the dry gas into the main supply line in a state where the first heater is controlled to heat the first region; and a substrate treating operation of supplying the humidified gas into the main supply line after the heating operation and allowing the humidified gas to pass through the first region and the second region and to be supplied into the treatment space to treat the substrate disposed in the treatment space.

According to the exemplary embodiment, the method may further include a measuring operation of measuring a temperature of the second region, in which the measuring operation may include measuring a temperature of a portion of the second region adjacent to the chamber.

According to the exemplary embodiment, the preset temperature value may be set to a temperature higher than a dew point temperature of the humidified gas.

According to the exemplary embodiment, the substrate treating operation may include mixing and supplying the humidified gas and the dry gas.

According to the exemplary embodiment, the method may further include forming a photoresist film containing a metal or inorganic substance on the substrate prior to treating the substrate by using the substrate treating apparatus.

According to the exemplary embodiment, the method may further include turning on a power supply of the substrate treating apparatus.

Still another exemplary embodiment of the present invention provides a method of treating a substrate, which treats a substrate by using a substrate treating apparatus, the substrate treating apparatus including: a housing providing an inner space; a heat treating chamber provided in the inner space, and providing a treatment space in which a heating treatment is carried out on a substrate on which a photoresist film containing a metal or inorganic substance is formed; a humidified gas supply line for supplying humidified gas containing moisture to the treatment space; a dry gas supply line for supplying dry gas to the treatment space; and a main supply line connected to the humidified gas supply line and the dry gas supply line, and having a first region in which a first heater is installed, and a second region located downstream of the first region, the method including: a heating operation of heating the second region with the dry gas heated in the first region by supplying the dry gas into the main supply line in a state where the first heater is controlled to heat the first region; a measuring operation of measuring a temperature of a portion of the second region adjacent to the chamber; after the heating operation, a substrate loading operation of loading a substrate into the treatment space when a temperature of the second region is equal to or higher than a preset temperature; and a substrate treating operation of supplying the humidified gas into the main supply line after the substrate loading operation and allowing the humidified gas to pass through the first region and the second region and to be supplied into the treatment space to treat the substrate disposed in the treatment space.

According to the exemplary embodiment, the preset temperature value may be set to a temperature higher than a dew point temperature of the humidified gas.

According to the exemplary embodiment, the substrate treating operation may include mixing and supplying the humidified gas and the dry gas.

According to the exemplary embodiment of the present invention, it is possible to prevent defects from being generated on the substrate when the substrate is heat treated.

Further, according to the exemplary embodiment of the present invention, when a substrate is treated by using humidified gas containing moisture, moisture condensation may be prevented by heating the humidified gas sufficiently even when a line heater is not provided in some areas of the line supplying the humidified gas.

Further, according to the exemplary embodiment of the present invention, it is possible to supply humidified gas containing moisture while maintaining stable humidity.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a cross-sectional view schematically illustrating one example of a liquid treating chamber of FIG. 3 or FIG. 4.

FIG. 7 is a top plan view schematically illustrating one example of the heat treating chamber of FIG. 3 or FIG. 4.

FIG. 8 is a front view of the heat treating chamber of FIG. 7.

FIG. 9 is a diagram illustrating a gas supply unit installed in a heating unit of FIG. 8.

FIG. 10 is a flowchart illustrating a method of treating a substrate according to an exemplary embodiment of the present invention.

FIG. 11 is a diagram schematically illustrating the flow of gas during a heating operation.

FIGS. 12 to 15 are diagrams illustrating the substrate treating apparatus performing a substrate loading operation.

FIGS. 16 and 17 are diagrams schematically illustrating the flow of gas during a substrate treating operation.

FIG. 18 is a diagram illustrating another exemplary embodiment of a gas supply unit.

FIG. 19 is a diagram illustrating another exemplary embodiment of a gas supply unit.

FIG. 20 is a diagram illustrating another exemplary embodiment of a gas supply unit.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

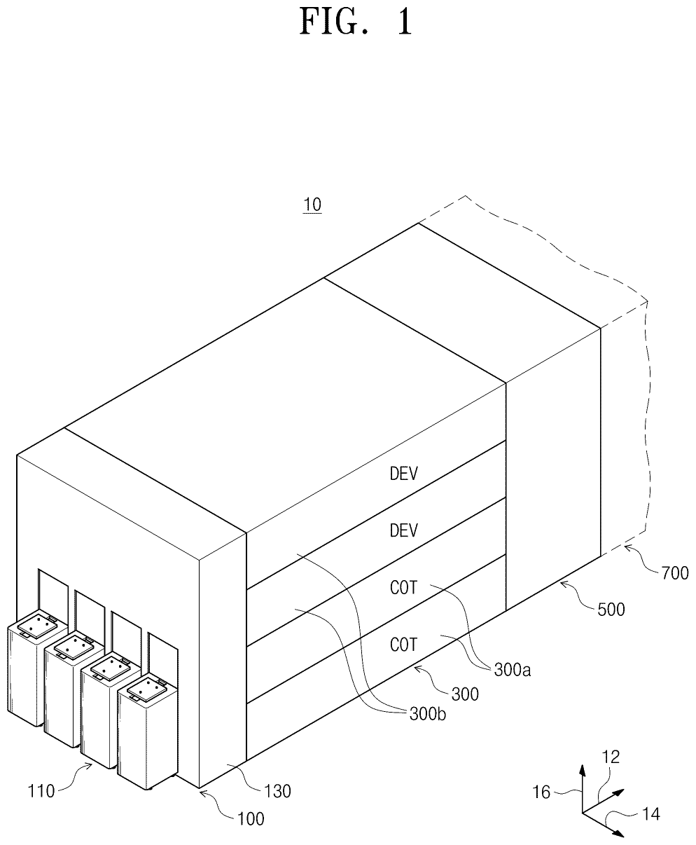

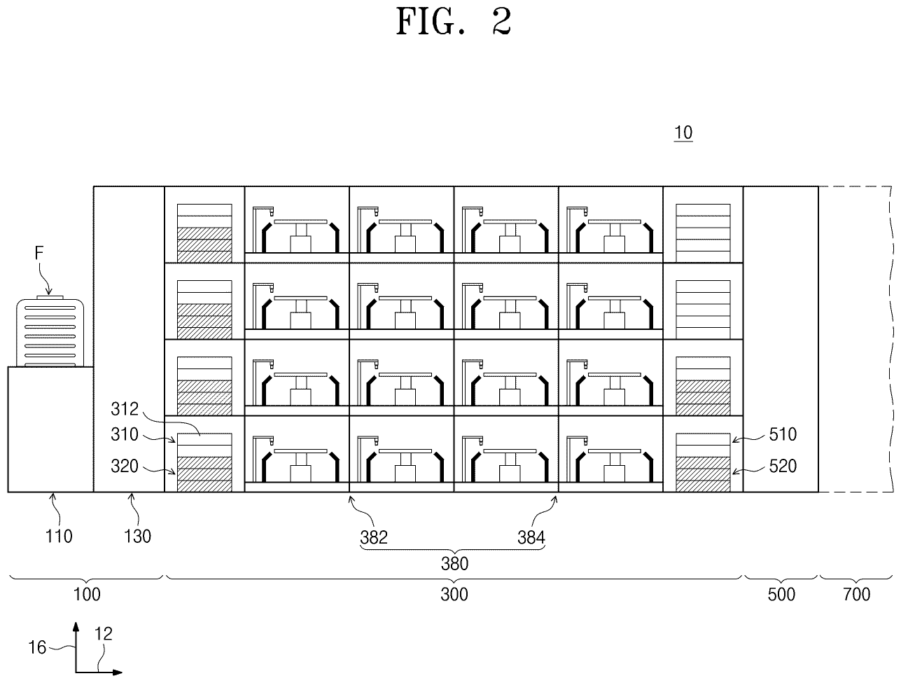

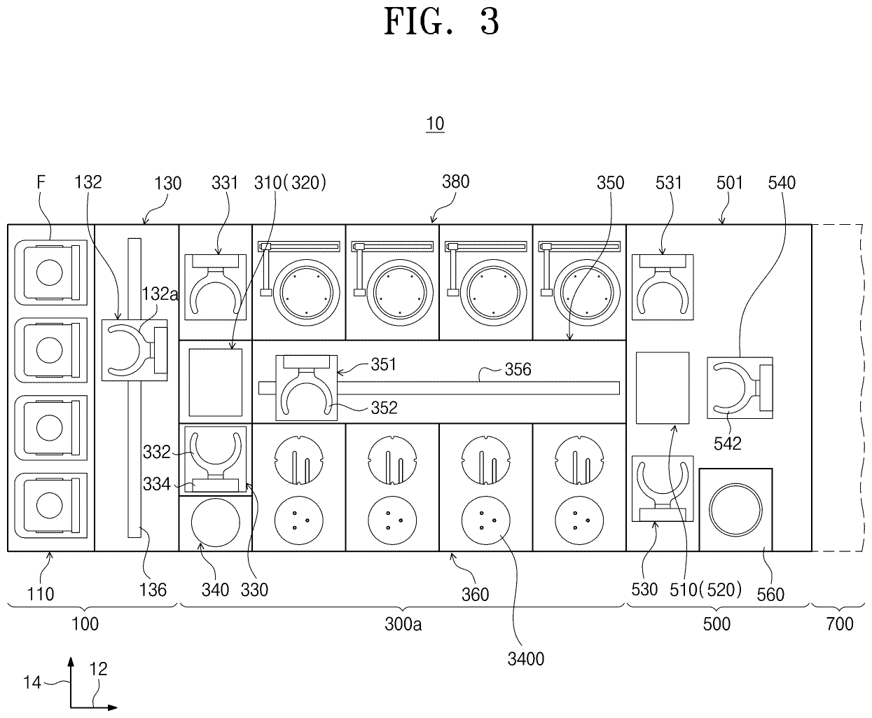

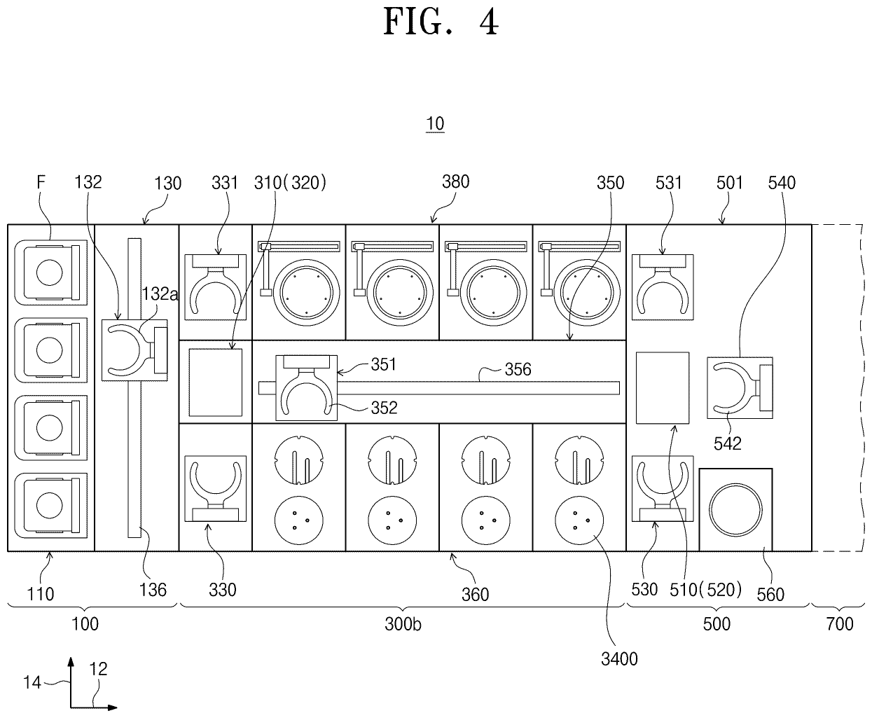

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 relative to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16. The treating module 300 performs an application process and a development process on the substrate W. The treating module 300 includes a coating block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be positioned below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing an irradiated region in a region of a register film on the substrate W may be performed in any one of the two developing blocks 300b, and a process for removing an unirradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided relative to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be positioned adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 1000 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the application block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the application block 300 may be disposed in overlapping positions.

The heat treating chamber 360 performs a heating process on the substrate W. The heating process includes a Post Exposure Baking (PEB) process, which is performed on the substrate W after the exposure process has been completed, and a hard baking process, which is performed on the substrate W after the development process has been completed.

The liquid treating chamber performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

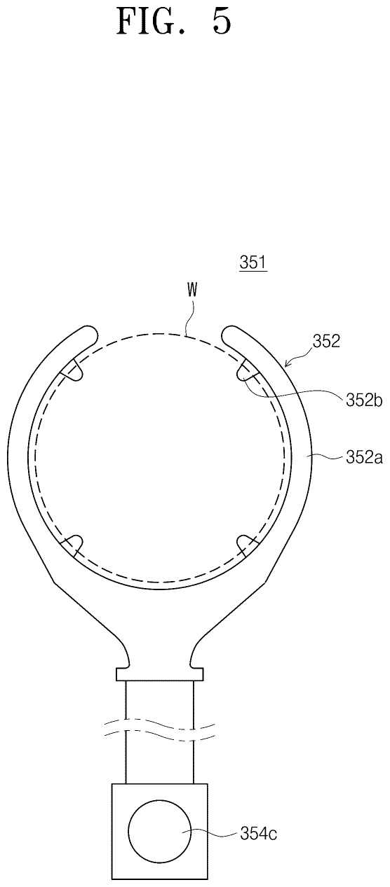

FIG. 5 is a diagram illustrating one example of the hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

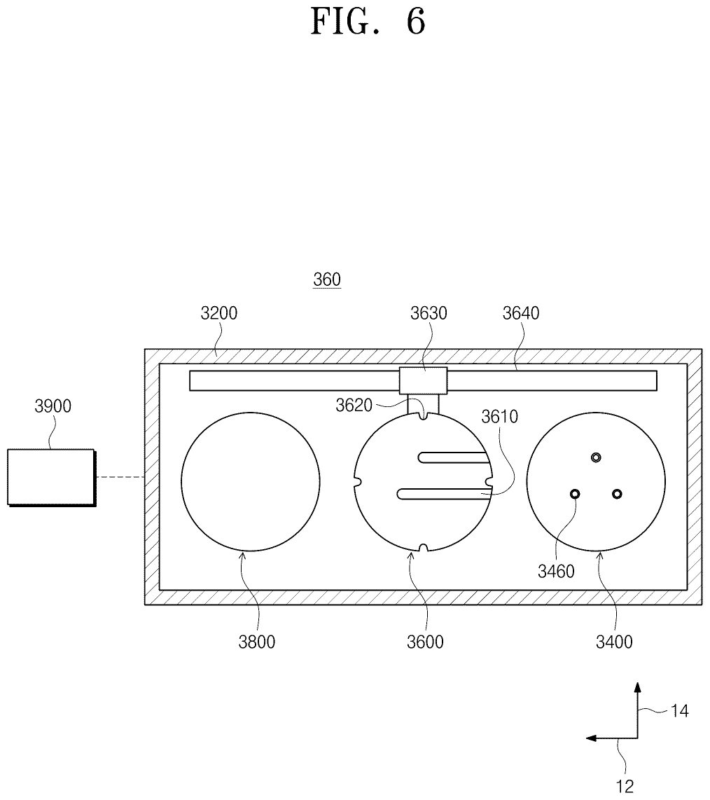

FIG. 6 is a front view schematically illustrating the liquid treating chamber of FIG. 3 or FIG. 4.

Referring to FIG. 6, the liquid treating chamber 380 includes a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

A support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

On the top wall of the housing 382 is disposed a fan filter unit 383 that supplies a downward airflow to the inner space. The fan filter unit 383 has a fan that introduces air from the outside into the inner space and a filter that filters the air from the outside.

The outer cup 384 has a bottom wall 384a, a sidewall 384b, and a top wall 384c. The inner of the outer cup 384 is provided as an inner space described above. The inner space H includes a treatment space at the top and an exhaust space at the bottom.

The bottom wall 384a is provided in a circular shape and has an opening in the center. The sidewall 384b extends upwardly from the outer end of the bottom wall 384a. The sidewall 384b is provided in a ring shape and is provided vertical to the bottom wall 384a. In one example, the sidewall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the sidewall 384b toward the center axis of the outer cup 384.

The guide cup 385 is positioned on the inner side of the outer cup 384. The guide cup 385 has an inner wall 385a, an outer wall 385b, and a top wall 385c. The inner wall 385a has a through hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the sidewall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. A gas-liquid separation plate 389 may be provided to extend upwardly from the bottom wall 384a of the outer cup 384. The gas-liquid separation plate 1230 may be provided in a ring shape. The gas-liquid separation plate 389 may be positioned between the sidewall 384b of the outer cup 384 and the outer wall 385b of the guide cup 385 when viewed from above. The top end of the gas-liquid separation plate 389 may be positioned lower than the bottom end of the outer wall 385b of the guide cup 385.

The bottom wall 384a of the outer cup 384 is connected to an outlet pipe 381a for discharging the treatment liquid and an exhaust pipe 381b. The outlet pipe 381a may be connected to the outer cup 384 from the outer side of the gas-liquid separation plate 389. The exhaust pipe 381b may be connected to the outer cup 384 from an inner side of the gas-liquid separation plate 389.

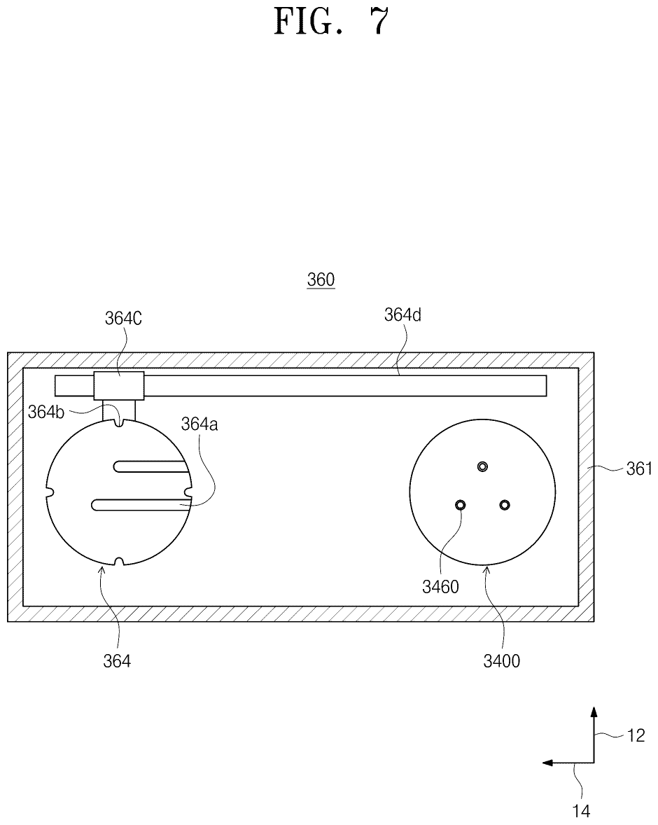

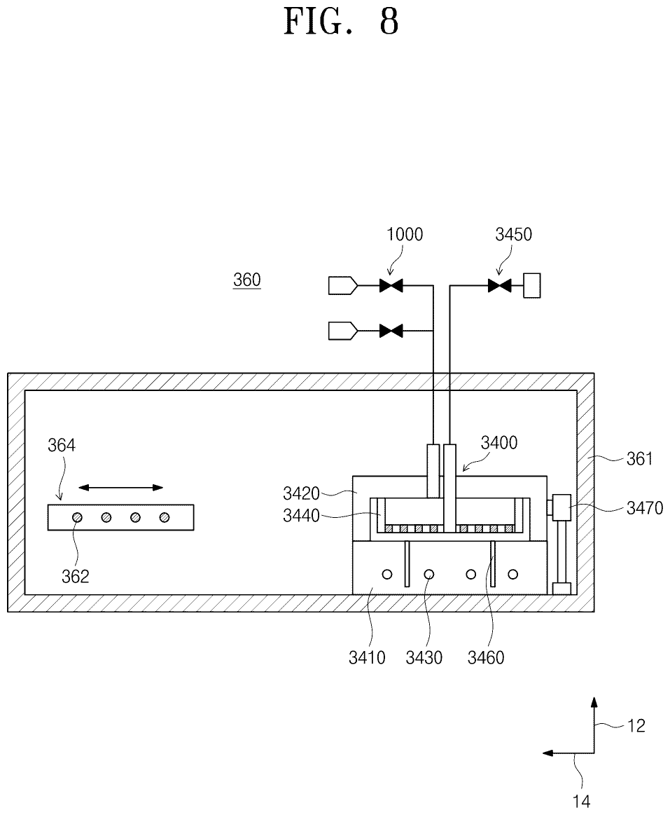

FIG. 7 is a top plan view schematically illustrating one example of the heat treating chamber of FIG. 3 or FIG. 4, and FIG. 8 is a front view of the heat treating chamber of FIG. 7. The discussion here focuses on the heat treating chamber 360, which provides humidified gas to heat treat the substrate. For example, the heat treating chamber 360 may be a chamber that performs a bake process after exposure.

Referring to FIGS. 7 and 8, the heat treating chamber 360 includes a housing 361, a heating unit 363, and a transfer plate 364.

The housing 361 is provided in the shape of a generally rectangular parallelepiped. In the sidewall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 3400.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands of the transfer robot 352 described above. Further, the notches 364b are provided in a number corresponding to the protrusions 352b formed on the hand, and are formed at locations corresponding to the protrusions 352b. In a position in which the hand and the transfer plate 364 are arranged in the vertical direction, the substrate W is transferred between the hand 354 and the transfer plate 364 when the vertical position of the hand and the transfer plate 364 is changed. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and the lifting pin 3460 from interfering with each other during the handover of the substrate W between the transfer plate 364 and the heating unit 3400.

The transfer plate 364 is provided with a thermally conductive material. In one example, the transfer plate 364 may be provided from a metal material.

A cooling flow path 364 is formed in the transfer plate 364. The cooling flow path 364 is supplied with coolant. The substrate W, which has been heated in the heating unit 3400, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 3400. The cooling unit may be provided as a cooling plate having a passage formed therein through which coolant flows. The substrate that has been heated in the heating unit may be returned to the cooling unit for cooling.

The heating unit 3400 includes a heating plate 3410, a cover 3420, a heater 3430, a shower head 3440, an exhaust member 3450, and a gas supply member 1000. The heating plate 3410 has a substantially circular shape when viewed from above. The heating plate 3410 has a diameter larger than the substrate W. A heater 3410 is installed in the heating plate 3430. The heater 3430 may be provided as a heating wire or heating pattern that is heated by the supply of electrical power. The heating plate 3410 is provided with a lift pin 3460. The lift pin 3460 is provided to be movable in an upward and downward direction along the third direction 16. The lift pin 3460 may receive the substrate W from the robot 351 and place the received substrate W down on the heating plate 3410, or lift the substrate W from the heating plate 3410 and hand the substrate W over to the transfer robot 351. According to one example, three lift pins 3460 may be provided. The cover 3420 has a space with an open lower portion therein. The cover 3420 is positioned on top of the heating plate 3410 and is moved in an upward and downward direction by a driver 3470. The space formed by the cover 3420 and the heating plate 3410 according to the movement of the cover 3420 is provided as a treatment space 3201 for heating the substrate W. The shower head 3636 is mounted inside the cover 3633. The shower head 3636 has a sidewall 3633a and an injection plate 3636b inside the cover 3633. The sidewall 3636a is provided in a ring shape. The injection plate 3636b is positioned at the bottom end of the sidewall 3636a. The space enclosed by the sidewall 3636a and the injection plate 3636b is provided as a gas introduction space R1. A plurality of injection holes 3636c is formed in the injection plate 3636b. The plurality of injection holes 3636c may be formed uniformly over the entire region of the injection plate 3636b.

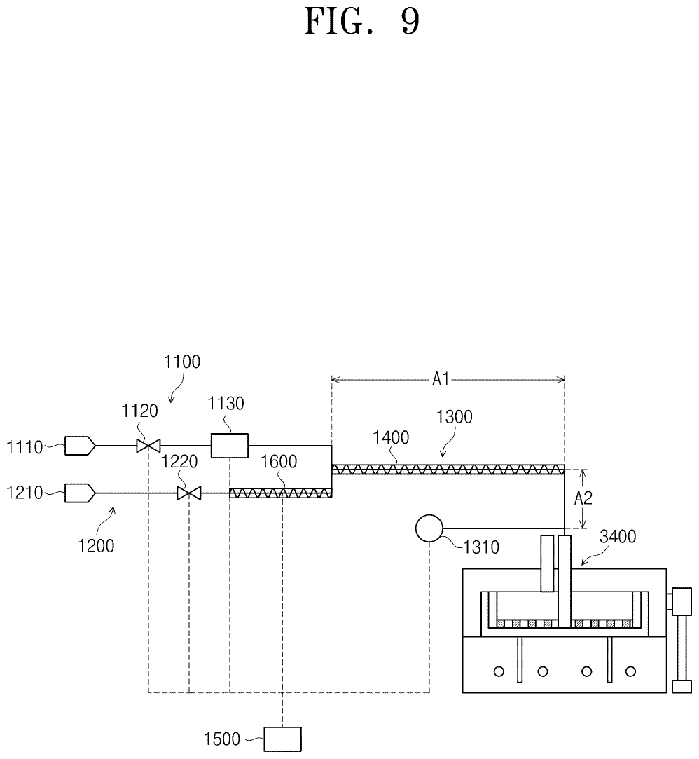

FIG. 9 is a diagram illustrating the gas supply unit installed in the heating unit of FIG. 8.

The gas supply unit 1000 includes a humidified gas supply line 1100, a dry gas supply line 1200, a main supply line 1300, a first heater 1400, and a controller 1500.

The humidified gas supply line 1100 supplies humidified gas to a treatment space T. The humidified gas contains moisture. In one example, the humidified gas may be provided as air containing moisture. The humidified gas supply line 1100 connects the humidified gas supply source 1110 to the main supply line 1300, which will be described later. A humidification unit 1130 is installed in the humidified gas supply line 1100. The humidification unit 1130 provides moisture to the gas. In one example, the humidified unit 1130 may heat the moisture to generate water vapor. Accordingly, the gas passing through the humidified unit 1130 may contain moisture. Further, a first valve 1120 is installed in the humidified gas supply line 1100. The first valve 1120 may be an open/close valve. Optionally, a flow control valve may further be installed in the humidified gas supply line 1100.

The dry gas supply line 1200 supplies dry gas to the treatment space T. In one example, the dry gas is N₂, inert gas, or air. The dry gas supply line 1200 connects a dry gas supply source 1210 to the main supply line 1300, which will be described later. A second heater 1600 may be installed in the dry gas supply line 1200. The second heater 1600 heats the dry gas supply line 1200. In one example, the second heater 1600 may be provided as a line heater. The second heater 1600 may be provided to surround the dry gas supply line. In addition, a second valve 1220 is installed in the dry gas supply line 1200. The second valve 1220 may be an open/close valve. Optionally, the dry gas supply line 1200 may further be provided with a flow control valve.

The main supply line 1300 supplies gas selected from humidified gas and dry gas to the treatment space T. The humidified gas supply line 1100 and the dry gas supply line 1200 are connected to the main supply line 1300. A first heater 1400 is installed on the main supply line 1300. The first heater 1400 heats the main supply line 1300. In one example, the first heater 1400 may be provided as a line heater. The main supply line 1300 includes a first region A1 and a second region A2. The first region A1 is located upstream of the second region A2. In one example, the second region A2 may be a region adjacent to the heating unit 3400.

The first heater 1400 is installed in only the first region A1 between the first region A1 and the second region A2. The second region A2 may be a region where the first heater 1400 is not easily installed due to interference with other equipment, components, or the like. Further, a temperature sensor 1310 may be installed in the main supply line 1300. The temperature sensor 1310 measures the temperature of the main supply line 1300. The temperature sensor 1310 may be installed in the second region A2. In one example, the temperature sensor 1310 may be installed in a region of the second region A2 adjacent to the heat treating chamber 360.

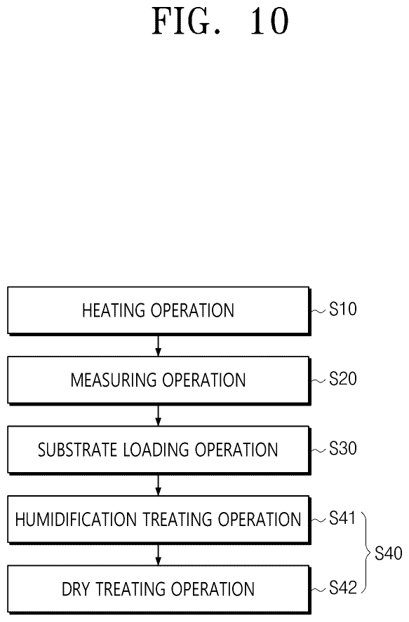

In the following, a method of heat treating the substrate W in the heating unit 3400 will be described in detail. FIG. 10 is a flowchart illustrating a method of treating a substrate according to an exemplary embodiment of the present invention. The controller 30 may control the substrate treating apparatus so as to perform a substrate treatment method to be described below. The controller 1500 may control components provided in the gas supply unit 1000 to perform the substrate treating method described below. For example, the components may be the first valve 1120, the second valve 1220, the first heater 1400, the second heater 1600, the humidification unit 1130, and the like. The controller 1500 may also control each of the valves 1410, 1510, 1521, and 1531 based on temperature and pressure transmitted from the temperature sensor 1330 and the pressure sensor 1340.

The controller 1500 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The following describes a method of treating a substrate by using the substrate treating apparatus according to an exemplary embodiment of the present invention. The substrate treating method includes a heating operation S10, a substrate loading operation S30, and a substrate treating operation S40.

The temperature of the second region A2 may decrease when a process for treating the substrate W has been performed for a long time, and when the power is turned off for maintenance of the device, and the like. Therefore, when no treatment has been performed on the substrate W for a certain period of time, a heating operation is performed before treating a new substrate W.

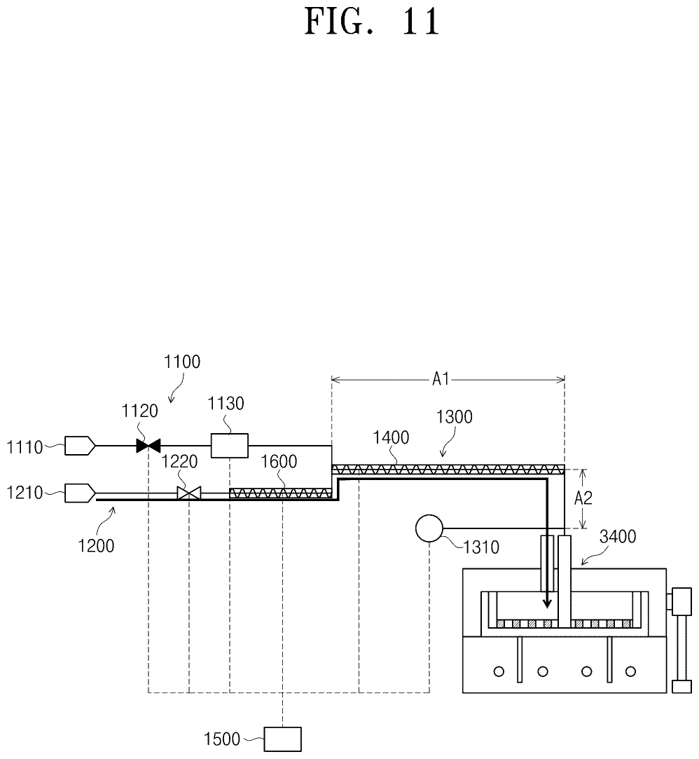

FIG. 11 is a diagram schematically illustrating the flow of gas during the heating operation.

As illustrated in FIG. 11, the temperature of the second region A2 is increased during the heating operation S10. When the temperature of the second region A2 is lower than the dew point temperature of the humidified gas, the controller 1500 heats the first heater 1400. The first heater 1400 heats the first region A1. The first heater 1400 may heat the first region A1 to a temperature higher than the dew point temperature of the humidified gas. In one example, the first heater 400 may heat the first region A1 to a temperature higher by 5 to 10° C. than the dew point temperature of the humidified gas. Further, the controller 1500 may heat the second heater 1600. The second heater 1600 may heat the dry gas supply line. The second heater 1600 can heat the dry gas supply line to a temperature higher than the dew point temperature of the humidified gas. In one example, the second heater 1600 may heat the dry gas supply line to a temperature higher by 5 to 10° C. than the dew point temperature of the humidified gas.

The controller 1500 closes the first valve 1120 and opens the second valve 1220. Accordingly, the supply of the humidified gas is blocked and the dry gas is supplied. The dry gas is supplied through the dry gas supply line 1200, the first region A1, the second region A2 and into the treatment space T. The dry gas is heated by the first heater 1400 and the second heater 1600. The second region A2 can be heated by the heated dry gas. The dry gas supplied to the treatment space T is then exhausted by an exhaust unit (not illustrated).

The temperature sensor 1310 measures the temperature of the second region A2. In one example, the temperature is measured in a region of the second region A2 adjacent to the heat treating chamber 360. The temperature sensor 1310 transmits the measured temperature to the controller 1500. The controller 1500 may compare the temperature of the second region A2 to the dew point temperature of the humidified gas. In one example, the controller 1500 may store and determine data regarding the dew point temperature of the humidified gas based on the humidity of the humidified gas.

After the heating operation S10, the measuring operation S20 may be performed. During the measuring operation S20, the temperature sensor 1310 continuously measures the temperature of the second region A2. When the temperature reaches a preset temperature value, the controller 1500 controls the first valve 1120 and the second valve 1220 to close. This shuts off the supply of humidified gas and dry gas to the treatment space T. Subsequently, the substrate loading operation S30 is performed.

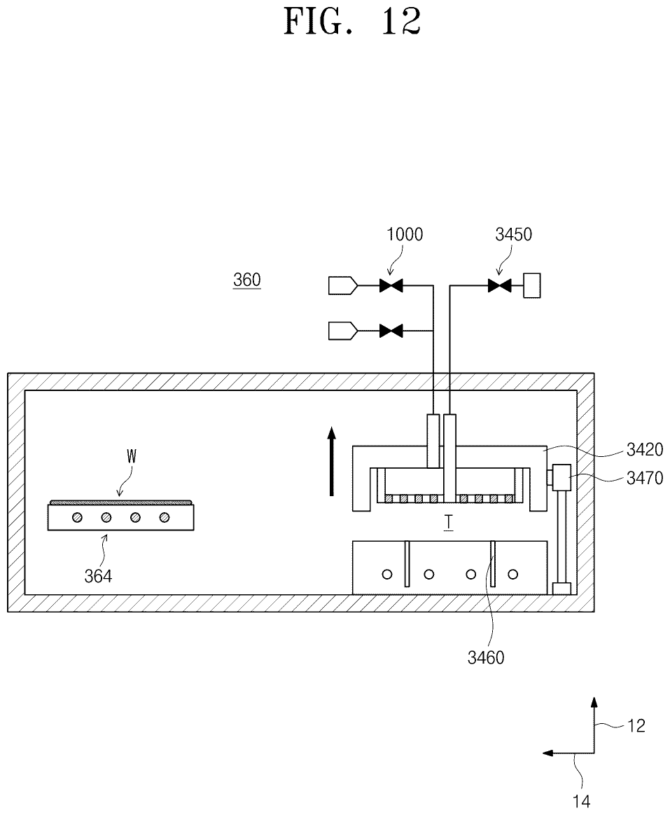

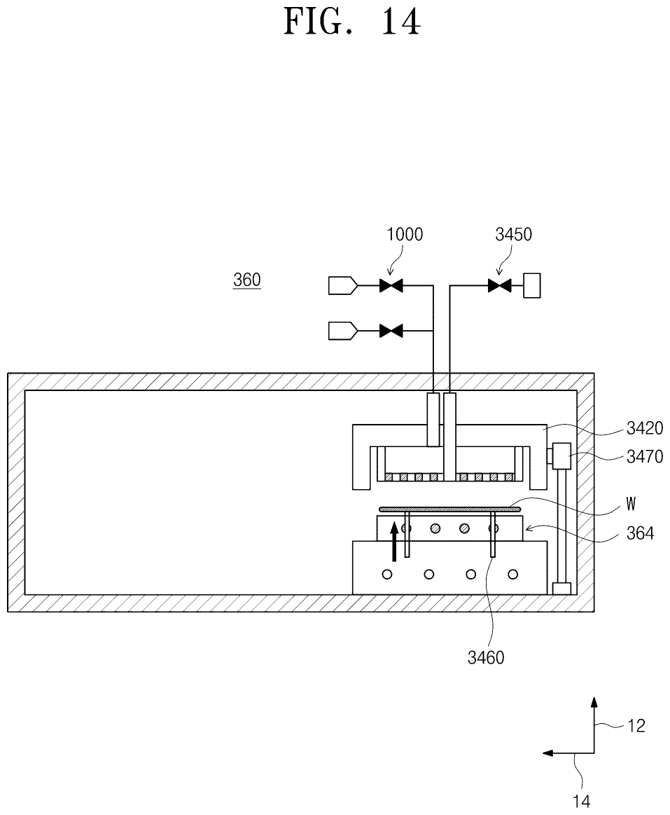

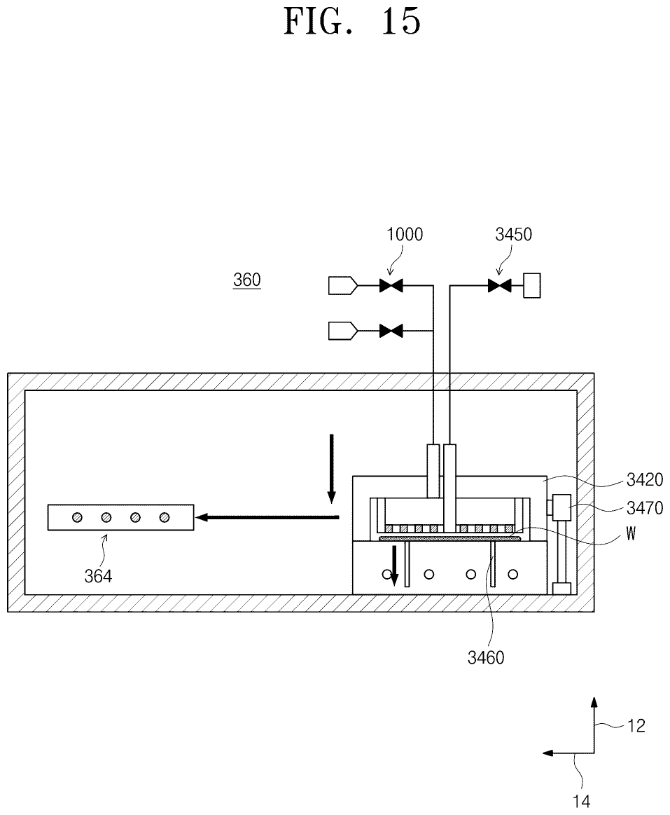

FIGS. 12 to 15 are diagrams illustrating the substrate treating apparatus performing the substrate loading operation. The gas supply unit 1000 illustrated in FIGS. 12 to 15 is illustrated schematically.

Referring to FIGS. 12 to 15, in the substrate loading operation S30, the substrate W is loaded into the treatment space T. The substrate W may have already been brought into the inner space by the transfer plate 364. The cover 3420 is raised by the driver 3470. The transfer plate 364 then loads the substrate W into the treatment space T. The lift pin 3460 rises to take over the substrate W from the transfer plate 364. The lift pin 3460 is lowered, and the heating plate 3410 supports the substrate W.

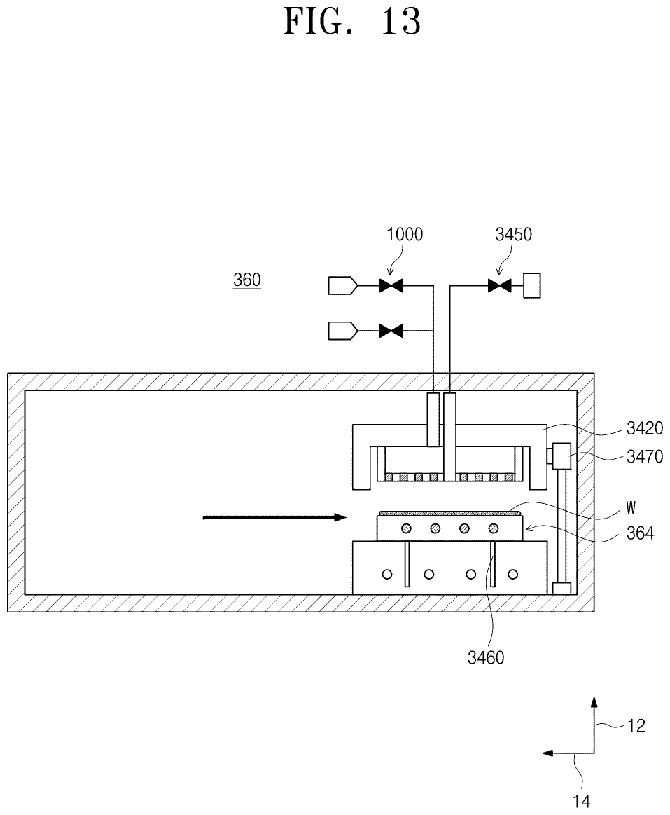

After the loading of the substrate W is completed, the substrate treating operation S40 is performed. FIG. 13 is a diagram illustrating the substrate treating apparatus performing the substrate treating operation.

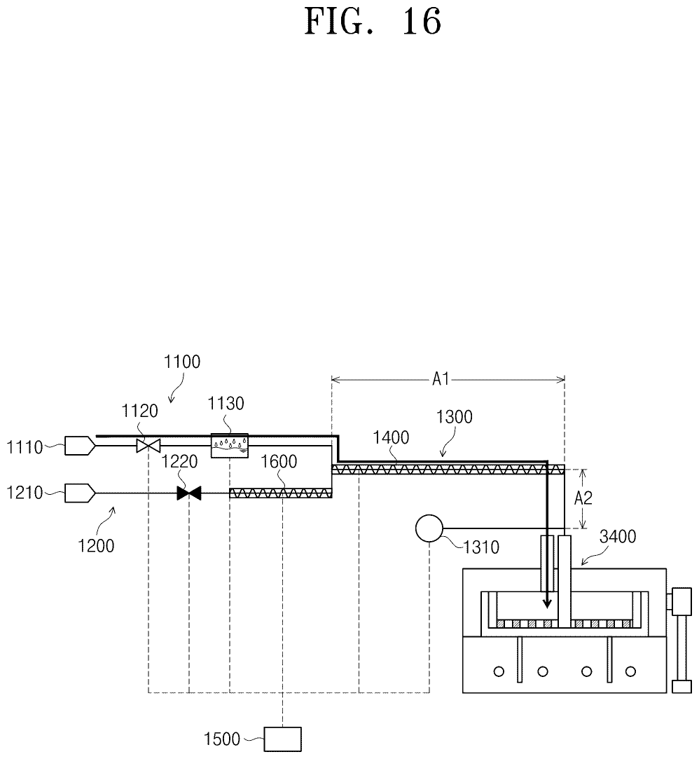

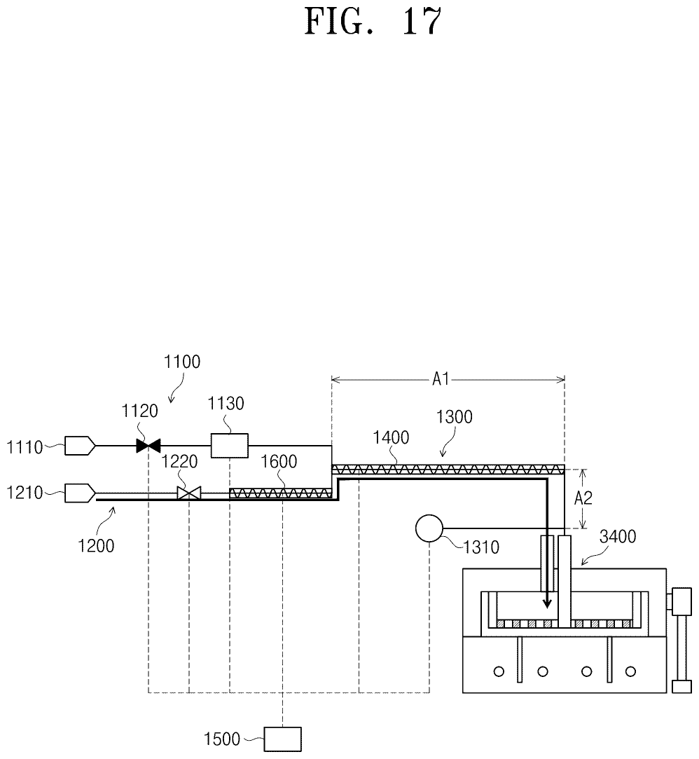

Referring to FIGS. 16 and 17, the substrate is treated during the substrate treating operation S40. During the substrate treating operation, the heating unit 3400 heats the substrate W. Further, the substrate treating operation S40 may include a humidification treating operation S41 and a drying treating operation S42. In one example, the humidification treating operation S41 heat treats the substrate W while supplying humidified gas. Furthermore, the drying treating operation S42 heat treats the substrate W while supplying dry gas. During the humidification treating operation S41, the controller 1500 opens the first valve 1120 and closes the second valve 1220. Accordingly, the humidified gas is supplied to the treatment space T and the dry gas is blocked. After a period of time, the drying treating operation S42 is performed. During the drying treating operation S42, the controller 1500 closes the first valve 1120 and opens the second valve 1220. Accordingly, the humidified gas is shut off to the treatment space T and the dry gas is supplied. The dry gas removes moisture from the substrate W. The substrate W is then removed from the treatment space T by the transfer unit 364.

According to the exemplary embodiment of the invention, the second region A2 is heated to the dew point temperature of the humidified gas or higher. Thus, even when the humidified gas passes through the second region A2, condensation of moisture in the humidified gas can be prevented. Therefore, the humidity of the humidified gas can be supplied to the treatment space T while maintaining a stable humidity. Furthermore, watermarks on the substrate W can be prevented from being formed, thereby preventing defects from occurring. Furthermore, when humidified gas is mixed with dry gas, the dew point temperature of the humidified gas can be controlled by adjusting the flow rate of the dry gas to prevent condensation of moisture in the gas.

Referring again to FIGS. 1 to 4, the interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided relative to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 includes a hand 542 on which the substrate W is placed, and the hand 542 may be provided to be movable forwardly and backwardly, rotatable about the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

In the example described above, the present invention has been described based on the case where the controller 1500 compares the temperature of the second region A2 to the dew point temperature of the humidified gas as an example. However, the present invention is not limited thereto, and it is possible to preset a temperature at which condensation does not occur in the humidified gas.

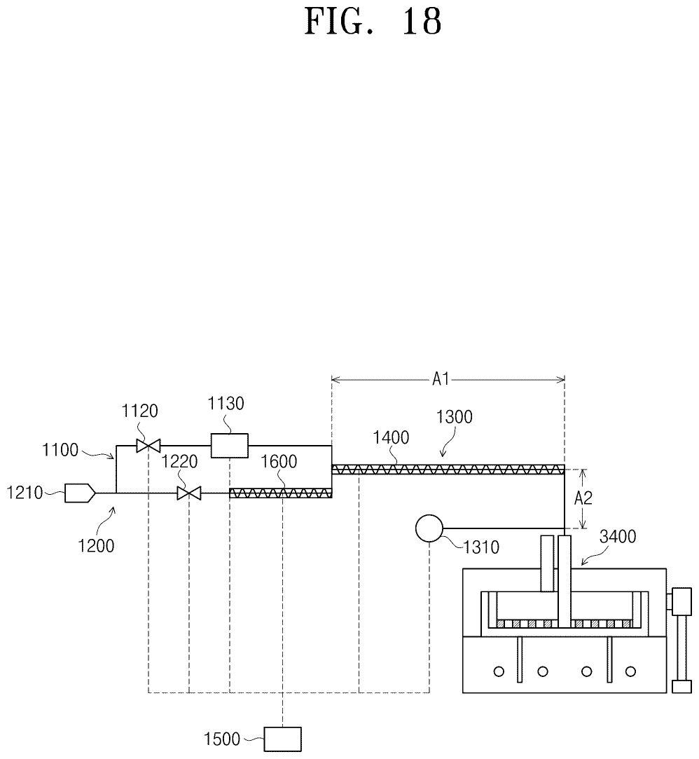

Also, in the above example, the present invention has been described based on the case where the humidified gas supply line 1100 and the dry gas supply line 1200 are provided separately as an example. However, the present invention is not limited thereto, and the single gas supply line 1800 may be provided, the humidification unit 1130 may be installed, and the humidification unit 1130 may be controlled to supply humidified gas or dry gas to the treatment space T, as illustrated in FIG. 18.

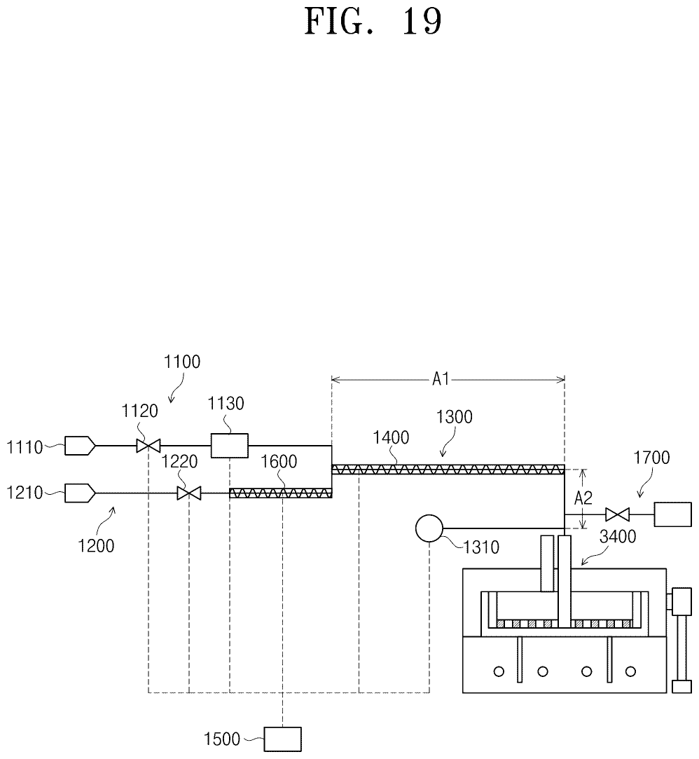

Further, in the example described above, the present invention has been described based on the case where dry gas is exhausted through the exhaust member 3450 during the heating operation S10 as an example. However, the present invention is not limited thereto, and the dry gas may be exhausted through a separate exhaust line formed by being branched in a region in which the second region A2 and the heating unit 3400 are adjacent, as illustrated in FIG. 19.

Further, in the examples described above, the present invention has been described based on the case where the second heater is provided as an example. However, the present invention is not limited thereto, and the second heater may not be provided.

Also, in the above example, the present invention has been described based on the case where the first heater and the second heater are provided as line heaters. However, the present invention is not limited thereto, and it is sufficient as long as the first heater and the second heater are means capable of heating the dry gas supply line 1200 and the main supply line 1300.

Furthermore, in the above example, the present invention has been described based on the heat treating chamber that performs a heat treatment after exposure as an example. However, the present invention is not limited thereto, and the heat treating chamber may be a chamber that performs a heat treatment process before exposure.

Furthermore, in the example described above, the measuring operation S20 is performed after the heating operation S10. However, the present invention is not limited thereto, and the measuring operation S20 may be performed before the heating operation S10 and may be performed at any point in time.

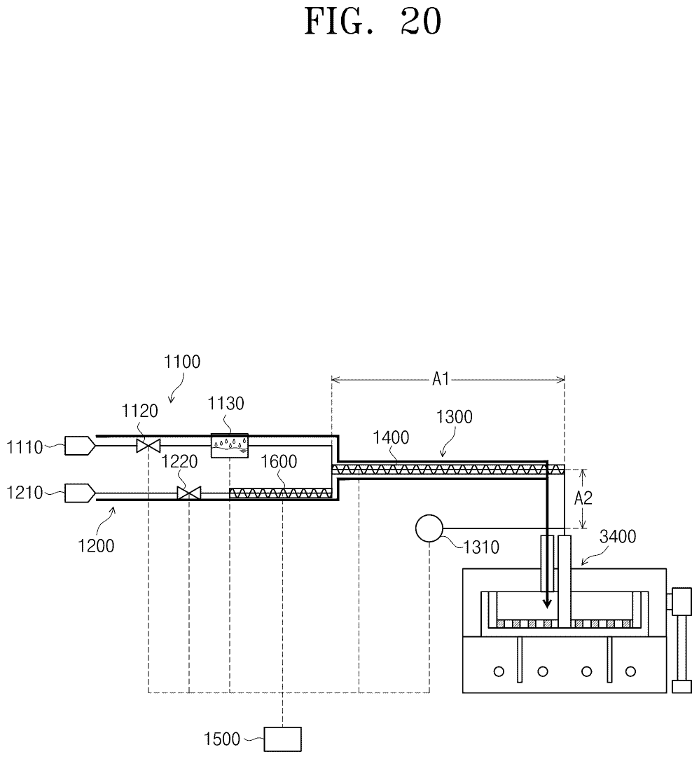

Furthermore, in the above example, the present invention has been described based on the case where only humidified gas is supplied during the humidification treating operation S41 as an example. However, as illustrated in FIG. 20, humidified gas and dry gas may be supplied together to adjust the humidity of the humidified gas.

In addition in, the above example, the present invention has been described based on the process for heat treating the substrate as an example. However, the present invention is not limited thereto, and the present invention is applicable to other types of processes where a substrate is treated by supplying humidified gas.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

1.-11. (canceled)

12. A method of treating a substrate, which treats a substrate by using a substrate treating apparatus, the substrate treating apparatus including: a heat treating chamber providing a treatment space in which a heating process of a substrate is carried out; a humidified gas supply line for supplying humidified gas containing moisture to the treatment space; a dry gas supply line for supplying dry gas to the treatment space; and a main supply line connected to the humidified gas supply line and the dry gas supply line, having a first region in which a first heater is installed, and a second region located downstream of the first region, the method comprising:
a heating operation of heating the second region with the dry gas heated in the first region by supplying the dry gas into the main supply line in a state where the first heater is controlled to heat the first region; and
a substrate treating operation of supplying the humidified gas into the main supply line after the heating operation and allowing the humidified gas to pass through the first region and the second region and to be supplied into the treatment space to treat the substrate disposed in the treatment space.

13. The method of claim 12, further comprising:
a measuring operation of measuring a temperature of the second region,
wherein the measuring operation includes measuring a temperature of a portion of the second region adjacent to the chamber.

14. The method of claim 12, wherein the preset temperature value is set to a temperature higher than a dew point temperature of the humidified gas.

15. The method of claim 12, wherein the substrate treating operation includes mixing and supplying the humidified gas and the dry gas.

16. The method of claim 12, further comprising:
forming a photoresist film containing a metal or inorganic substance on the substrate prior to treating the substrate by using the substrate treating apparatus.

17. The method of claim 12, further comprising:
turning on a power supply of the substrate treating apparatus.

18. A method of treating a substrate, which treats a substrate by using a substrate treating apparatus, the substrate treating apparatus including: a housing providing an inner space; a heat treating chamber provided in the inner space, and providing a treatment space in which a heating treatment is carried out on a substrate on which a photoresist film containing a metal or inorganic substance is formed; a humidified gas supply line for supplying humidified gas containing moisture to the treatment space; a dry gas supply line for supplying dry gas to the treatment space; and a main supply line connected to the humidified gas supply line and the dry gas supply line, and having a first region in which a first heater is installed, and a second region located downstream of the first region, the method comprising:
a heating operation of heating the second region with the dry gas heated in the first region by supplying the dry gas into the main supply line in a state where the first heater is controlled to heat the first region;
a measuring operation of measuring a temperature of a portion of the second region adjacent to the chamber;
after the heating operation, a substrate loading operation of loading a substrate into the treatment space when a temperature of the second region is equal to or higher than a preset temperature value; and
a substrate treating operation of supplying the humidified gas into the main supply line after the substrate loading operation and allowing the humidified gas to pass through the first region and the second region and to be supplied into the treatment space to treat the substrate disposed in the treatment space.

19. The method of claim 18, wherein the preset temperature value is set to a temperature higher than a dew point temperature of the humidified gas.

20. The method of claim 18, wherein the substrate treating operation includes mixing and supplying the humidified gas and the dry gas.
